(19) United States
(12) Patent Application Publication
(10) Pub. No.: US 2012/0261171 A1
(43) Pub. Date: Oct. 18, 2012

(54) ANISOTROPIC CONDUCTIVE FILM, JOINED STRUCTURE, AND CONNECTING METHOD

(75) Inventors: Yasunobu YAMADA, Kanuma-shi (JP); Koichi Miyauchi, Kanuma-shi (JP)

(73) Assignee: Sony Chemical & Information Device Corporation, Shinagawa-ku (JP)

(21) Appl. No.: 13/534,667

(22) Filed: Jun. 27, 2012

Related U.S. Application Data
(63) Continuation of application No. PCT/JP2011/051008, filed on Jan. 20, 2011.

(30) Foreign Application Priority Data
Feb. 1, 2010 (JP) 2010-019974

(51) Int. Cl. H05K 1/18; H05K 1/03

(52) U.S. Cl. 174/255; 174/260

(57) ABSTRACT

To provide an anisotropic conductive film, which contains: an electric conductive layer containing Ni particles, metal-coated resin particles, a binder, a polymerizable monomer, and a curing agent; and an insulating layer containing a binder, a monofunctional polymerizable monomer, and a curing agent, wherein the metal-coated resin particles are resin particles each containing a resin core coated at least with Ni.

### CROSS-REFERENCE TO RELATED APPLICATION

This is a continuation of Application No. PCT/JP2011/051008, filed on Jan. 20, 2011.

### BACKGROUND OF THE INVENTION

1. Field of the Invention

The present invention relates to an anisotropic conductive film having both high conduction reliability and high bonding strength, which is particularly suitable for connecting COF with PWB, and relates to a joined structure and connecting method using the anisotropic conductive film.

2. Description of the Related Art

When a driver IC is fabricated on a liquid crystal display (LCD), as a common method, a COF (Chip On Film), on which the driver IC has been fabricated on a flexible board (FPC) in advance, is thermally bonded to the LCD and to a printed wiring board (PWB) via an anisotropic conductive film (ACF).

In this case, electric connection between the LCD and the COF, or the COF and the PWB can be achieved by bonding them with the ACF. In addition, insulating properties can be maintained between adjacent electrodes, and the ACF also gives bonding strength so that the LCD and the COF, or the COF and the PWB are not pealed from each other by external force.

To reduce a cost of a LCD module, it has been currently actively studied to make one COF have multiple outputs (i.e. fine pitch) to reduce the number of parts in the COF.

As the pitch becomes finer, however, it is more difficult to accurately position and align the patterns during thermal pressure bonding with the ACF. Considering the degree of difficulties of positioning the pattern on the LCD with the pattern of the COF, and positioning the pattern of the COF and the pattern on the PWB, the former can be handled by previously modifying the pitch of the pattern of the COF as the LCD side is a glass and therefore the thermal expansion degree thereof is stable, though the pitch of the pattern is finer than the latter.

On the other hand, the latter is difficult to position because the glass of the PWB and the thickness of the epoxy material are not qualitatively stable and the thermal expansion degree thereof is not stable. In addition, the glass transition temperature (Tg) of the FR-4 specification of a commonly used PWB is 110° C. to 130° C., and therefore the temperature of the pressure bonding is preferably lower than the glass transition temperature thereof to prevent a warp of the PWB, or to reduce a damage on the connection part of the ACF. To this end, low temperature bonding is desired for connecting between the COF and the PWB. Further, there are currently also demands for bonding over a short period to improve the productivity.

If low temperature bonding and short period bonding abilities are imparted to the ACF and the mechanical strength of the binder cured product of the ACF is enhanced to improve the conduction reliability, however, the bonding strength (peel strength in the 90° Y axis direction) at the bonding part between the COF and PWB tends to be low. This is probably because the polyimide material of the COF and the binder o the ACF do not sufficiently wet and it is difficult to form chemical bonding between these materials as the binder is quickly cured in the low temperature region, and because the deformability of the binder cured product itself is low in the bonding part when the peel strength in the 90° Y axis direction and the absorption energy for deforming is low, as the binder cured product is hard.

If the mechanical strength (i.e. elastic modulus) of the binder cured product is designed low to enhance the deformability of the binder cured product in the bonding part during the measurement of the peel strength in the 90° Y axis direction, the bonding strength increases, but the conduction reliability is impaired.

As mentioned above, to balance out between the improvement of the bonding strength with the COF and the improvement of the conduction reliability of a tape carrier package (TCP) is one of the extremely difficult problems to be solved.

Moreover, there is a problem that a sufficient peel strength cannot be attained depending on a type of the COF. In order to closely adhere an anisotropic conductive film to a COF that is difficult to adhere to (i.e., having low peel strength), a formula of a binder of the ACF can be optimized. If the formula is optimized for one particular COF, however, such an ACF may be difficult to adhere to other COFs.

The LCD module is generally completed by mounting the COF onto the LCD panel. When this LCD module is assembled in a housing, external stress is temporarily applied to the bonding parts of the ACFs between the LCD panel and the COF, and between the COF and the PWB.

Experientially, a possibility that the bonding part between the COF and the ACF is peeled is high when the LCD module packaged in the housing, unless the peel strength of the LCD panel and the COF and that of the COF and the PWB are 4 N/cm or higher. As the peal strength of the LCD panel and the COF, and that of the COF and the PWB are higher, the resulting the LCD modulus has more resistance to the external stress applied during the packaging, which improves handling ability.

In order to provide high adhesiveness to various COFs, the glass transition temperature (Tg) and elastic modulus of the binder of the ACF are reduced to thereby widen the adhesion margin to each subject to be adhered. In this case, however, the binder tends to be loosen in the high temperature high humidity environment (85° C., 85% RH), and therefore there is a problem of increasing the conduction resistance.

To solve the aforementioned problems, various attempts have been made in the conventional art. For example, Japanese Patent Application Laid-Open (JP-A) Nos. 2007-211122 and 2004-238738 discloses an ACF using Ni particles.

Moreover, JP-A Nos. 2009-500804, 2008-159586, and 2004-14409 discloses electric conductive particles in each of which a resin core is plated with Ni, whose outer shell is plated with Au, and discloses an ACF using such the electric conductive particles.

JP-A No. 2007-242731 discloses an ACF containing particles in each of which a resin core is plated with Ni, whose outer shell is plated with Ag.

Further, JP-A No. 11-339558 discloses an ACF containing hard electric conductive particles and soft electric conductive particles. As for the hard electric conductive particles, gold-plated nickel is used. As for the soft electric conductive particles, gold-plated crosslinked polystyrene resin particles are used.

In any of the prior art documents, however, an anisotropic conductive film having high bonding strength under the conditions of low temperature and short time (at 130° C. for 3 seconds) and excellent conduction reliability, as well as a joined structure and connection method using such the anisotropic conductive film have not been provided yet. Accordingly, there have been demands for promptly providing such the anisotropic conductive film, as well as a joined structure and connecting method using the same.

### SUMMARY OF THE INVENTION

The present invention aims to solve the various problems in the art, and to achieve the following object. An object of the present invention is to provide an anisotropic conductive film having both high bonding strength under the conditions of low temperature and short period, and excellent conduction reliability, and to provide a joined structure and connecting method using the anisotropic conductive film.

The present inventors have conducted diligent studies to solve the aforementioned problems. As a result, it has been found that the following anisotropic conductive film has high bonding strength even under conditions of low temperature and a short period, and has excellent conduction reliability. Namely, the anisotropic conductive film has a two⁻layer structure containing an insulating layer and an electric conductive layer, where the insulating layer contains a monofunctional monomer for attaining high bonding strength, and the electric conductive layer contains two types of electric conductive particles including Ni particles for breaking an oxide film on an electrode of a PWB and attaining low connection resistance, and resin particles, in each of which a resin core is at least coated with Ni, for attaining high conduction reliability. The present invention has been accomplished based on the insights of the present inventors, and the means for solving the aforementioned problems are as follows:
<1> An anisotropic conductive film, containing:

an electric conductive layer containing Ni particles, metal-coated resin particles, a binder, a polymerizable monomer, and a curing agent; and

an insulating layer containing a binder, a monofunctional polymerizable monomer, and a curing agent,

wherein the metal-coated resin particles are resin particles each containing a resin core coated at least with Ni.
<2> The anisotropic conductive film according to <1>, wherein the insulating layer contains at least a phenoxy resin, a monofunctional (meth)acryl monomer, and organic peroxide.
<3> The anisotropic conductive film according to any of <1> or <2>, wherein the electric conductive layer contains at least a phenoxy resin, a (meth)acryl monomer, and organic peroxide.
<4> The anisotropic conductive film according to any one of <1> to <3>, wherein the metal-coated resin particles are resin particles each containing a resin core coated with Ni, or resin particles each containing a resin core coated with Ni, whose outer surface is further coated with Au.
<5> The anisotropic conductive film according to any one of <1> to <4>, wherein a material of the resin core is a styrene-divinylbenzene copolymer, or a benzoguanamine resin.
<6> The anisotropic conductive film according to any one of <1> to <5>, wherein the metal-coated resin particles have the average particle diameter of 5 μm or greater.
<7> The anisotropic conductive film according to any one of <1> to <6>, wherein a total amount of the Ni particles and the metal-coated resin particles in the electric conductive layer is 3.0 parts by mass to 20 parts by mass relative to 100 parts of resin solids contained in the electric conductive layer.
<8> A joined structure, containing:

a first circuit member;

a second circuit member; and

the anisotropic conductive film as defined in any one of <1>to <7>,

wherein the first circuit member and the second circuit member are joined together with the anisotropic conductive film provided between the first circuit member and the second circuit member.
<9> The joined structure according to <8>, wherein the first circuit member is a printed wiring board and the second circuit member is a COF.
<10>A connecting method, containing:

providing an anisotropic conductive film between a first circuit member and a second circuit member; and

pressurizing the first circuit member and the second circuit member with heating to cure the anisotropic conductive film, to thereby connect the first circuit member with the second circuit member,

wherein the anisotropic conductive film is the anisotropic conductive film as defined in any one of <1> to <7>.
<11> The connecting method according to <10>, wherein the first circuit member is a printed wiring board and the second circuit member is a COF.
<12> The connecting method according to <11>, wherein the providing is arranging the anisotropic conductive film so that the electric conductive layer thereof comes to the side of the printed wiring board, and the insulating layer thereof comes to the side of the COF.

The present invention can solve the various problems in the art, achieve the aforementioned object, and can provide an anisotropic conductive film having both high bonding strength under the conditions of low temperature and short period, and excellent conduction reliability, as well as providing a joined structure and connecting method using the anisotropic conductive film.

### BRIEF DESCRIPTION OF THE DRAWINGS

FIG. 1 is a schematic diagram illustrating one example of the anisotropic conductive film of the present invention.

FIG. 2 is a schematic diagram illustrating one example of the joined structure of the present invention.

FIG. 3 is an explanatory diagram illustrating a method for measuring peel strength in Examples.

FIG. 4 is an explanatory diagram illustrating a method for measuring conduction resistance in Examples.

### DETAILED DESCRIPTION OF THE INVENTION

### (Anisotropic Conductive Film)

The anisotropic conductive film of the present invention contains at least an electric conductive layer, and an insulating layer, and may further contain a separation base, and other layers, if necessary.

The anisotropic conductive film is preferably an embodiment thereof where the anisotropic conductive film contains a separation base (separator), an insulating layer formed on the separation base (separator), and an electric conductive layer formed on the insulating layer. Note that, the anisotropic conductive film may be an embodiment where the anisotropic conductive film does not contain a separation base. When the anisotropic conductive film contains the separation base, the separation base is separated and removed for connecting with other members.

### <Insulating Layer>

The insulating layer contains a binder, a monofunctional polymerizable monomer, and a curing agent, and may further contain a silane coupling agent, and other components, if necessary.

Conventionally, a monofunctional monomer has not been used as a reactive main component of a binder for use in an anisotropic conductive film (ACF). The monofunctional monomer has been typically used for the purpose of giving tackiness to a film, or dissolving the binder. The reactive component consisting of the monofunctional monomer may form a sticky binder cured product, or binder cured product of low heat resistance. Therefore, the monofunctional monomer has not bee applied for an anisotropic conductive film to which high conduction reliability is required.

Meanwhile, it is desired that the binder of the anisotropic conductive film has high glass transition temperature (Tg), as the temperature may go up to about 40° C. to 60° C. when a COF driver is driven, Moreover, even when the monofunctional monomer is used, the mechanical strength can be increased by increasing the proportion of the binder in the formula. Therefore, in the anisotropic conductive film of the present invention having the two-layer structure including the electric conductive layer containing two types of the electric conductive particles, and the insulating layer, a problem does not occur in connection with the conduction properties, when the monofunctional monomer is used in the insulating layer.

Moreover, the anisotropic conductive film of the present invention has a so configuration such that the hard Ni particles contained in the electric conductive layer penetrate into a terminal, and the anisotropic conductive film is desired to have the binding strength (peel strength) enough to maintain this penetration of the Ni particles into the terminal. If the peel strength thereof is high at room temperature, the anisotropic conductive film can resist the external stress applied during the packaging, and can maintain the penetration of the Ni particles into the terminal

Accordingly, in the anisotropic conductive film of the present invention, the electric conductive layer contains two types of the electric conductive particles (Ni particles and resin particles in each of which a resin core is coated at least with Ni), and the insulating layer has a formulation of the binder, which contains a monofunctional monomer.

### —Binder—

The binder is appropriately selected depending on the intended purpose without any limitation, and examples thereof include a phenoxy resin, an epoxy resin, an unsaturated polyester resin, a saturated polyester resin, a urethane resin, a butadiene resin, a polyimide resin, a polyamide resin, and a polyolefin resin. These may be used independently, or in combination. Among them, the phenoxy resin is particularly preferable in view of film forming ability, processability; and connection reliability.

The phenoxy resin is a resin synthesized from bisphenol A and epichlorohydrin, and may be appropriately synthesized for use or appropriately selected from commercial products. Examples of the commercial products thereof under product names include YP-50 (manufactured by Nippon Steel Chemical Co., Ltd.), YP-70 (manufactured by Nippon Steel Chemical Co., Ltd.), and EP1256 (manufactured by Japan Epoxy Resins Co., Ltd.).

An amount of the binder in the insulating layer is appropriately selected depending on the intended purpose without any limitation, but for example, it is preferably 20% by mass to 70% by mass, more preferably 35% by mass to 55% by mass.

### —Monofunctional Polymerizable Monomer—

The monofunctional polymerizable monomer is appropriately selected depending on the intended purpose without any limitation, provided that it is a monomer containing at least one polymerizable group in a molecule thereof. Examples of the monofunctional polymerizable monomer include a (meth)acryl monomer, a styrene monomer, a butadiene monomer, and an olefin-based monomer containing a C═C bond. These may be used independently, or in combination. Among them, the monofunctional (meth)acryl monomer is particularly preferable in view of the bonding strength, and connection reliability.

The monofunctional (meth)acryl monomer is appropriately selected depending on the intended purpose without any limitation, and examples thereof include: acrylic acid or esters thereof, such as acrylic acid, methyl acrylate, ethyl acrylate, propyl acrylate, n-butyl acrylate, isobutyl acrylate, n-octyl acrylate, n-dodecyl acrylate, 2-ethylhexyl acrylate, stearyl acrylate, 2-chloroethyl acrylate, and phenyl acrylate; methacrylic acid or esters thereof, such as methacrylic acid, methyl methacrylate, ethyl methacrylate, propyl methacrylate, n-butyl methacrylate, isobutyl methacrylate, n-octyl methacrylate, n-dodecyl methacrylate, 2-ethylhexyl methacrylate, stearyl methacrylate, phenyl methacrylate, dimethylaminoethyl methacrylate, and diethylaminoethyl methacrylate. These may be used independently, or in combination.

An amount of the monofunctional polymerizable monomer in the insulating layer is appropriately selected depending on the intended purpose without any limitation, but it is preferably 2% by mass to 30% by mass, more preferably 5% by mass to 20% by mass.

### —Curing Agent—

The curing agent is appropriately selected depending on the intended purpose without any limitation, provided that it can cure the binder. For example, the curing agent is preferably organic peroxide.

Examples of the organic peroxide include lauroyl peroxide, butyl peroxide, benzyl peroxide, dilauroyl peroxide, dibutyl peroxide, benzyl peroxide, peroxydicarbonate, and benzoyl peroxide. These may be used independently, or in combination.

An amount of the curing agent in the insulating layer is appropriately selected depending on the intended purpose without any limitation, but it is preferably 1% by mass to 15% by mass, more preferably 3% by mass to 10% by mass.

### —Silane Coupling Agent—

The silane coupling agent is appropriately selected depending on the intended purpose without any limitation, and examples thereof include an epoxy-based silane coupling agent, an acryl-based silane coupling agent, a thiol-based silane coupling agent, and an amine-based silane coupling agent.

An amount of the silane coupling agent in the insulating layer is appropriately selected depending on the intended purpose without any limitation, but it is preferably 0.5% by mass to 10% by mass, more preferably 1% by mass to 5% by mass. —Other Components—

Other components are appropriately selected depending on the intended purpose without any limitation, and examples thereof include filler, a softening agent, an accelerator, an antioxidant, a colorant (pigment, dye), an organic solvent, and an ion catcher. An amount of any of other components to be added is appropriately selected depending on the intended purpose without any limitation.

The insulating layer can be formed by preparing a coating liquid for an insulating layer containing, for example, a binder, a monofunctional polymerizable monomer, a curing agent, preferably further containing a silane coupling agent, optionally further containing other components (e.g., an organic solvent), applying the coating liquid for an insulating layer onto a separation base (a separator), and drying to remove the organic solvent therein.

A thickness of the insulating layer is appropriately selected depending on the intended purpose without any limitation, but for example, it is preferably 10 μm to 25 μm, and more preferably 18 μm to 21 μm. When the thickness thereof is excessively small, the peel strength may be reduced. When the thickness thereof is excessively great, the conduction reliability may be impaired.

### <Electric Conductive Layer>

The electric conductive layer contains Ni particles, metal-coated resin particles, a binder, a polymerizable monomer, and a curing agent, and may further contain a silane coupling agent, and other components, if necessary.

### —Ni Particles—

The Ni particles are used for attaining low connection resistance. The Ni particles are appropriately selected depending on the intended purpose without any limitation, but it is preferred that the Ni particles have the average particle diameter of 1μm to 5μm. When the average particle diameter thereof is smaller than 1 μm, connection reliability may be impaired after the pressure bonding as the surface area of such Ni particle is small. When the average particle diameter thereof is greater than 5 μm, short circuit between wiring may occur when the wiring is laid with a fine pitch.

Note that, as for the Ni particles, Ni particles on each surface of which metal protrusions are present, or Ni particles on each surface of which an insulating film formed of an organic material is formed may be used.

The average particle diameter of the Ni particles denotes the number average particle diameter, which can be measured, for example, by a particle size distribution analyzer (MICROTRAC MT3100, manufactured by Nikkiso Co., Ltd.).

The hardness of the Ni particles is, for example, preferably 2,000 kgf/mm² to 6,000 kgf/mm². The hardness of the Ni particles can be determined, for example, from test force obtained by applying load to the Ni particles by means of a micro compression tester to make the Ni particles displace by 10%.

The Ni particles may be appropriately prepared for use, or selected from commercial products.

An amount of the Ni particles in the electric conductive layer is appropriately selected depending on the intended purpose without any limitation, but it is preferably 2 parts by mass to 10 parts by mass, more preferably 2 parts by mass to 8 parts by mass, relative to 100 parts by mass of the resin solids (a total amount of the binder, the polymerizable monomer, and the curing agent). When the amount thereof is excessively small, the conduction resistance may increase. When the amount thereof is excessively large, it is more likely to cause short circuit.

### —Metal-Coated Resin Particles—

As for the metal-coated resin particles, resin particles in each of which a resin core is coated at least with Ni are preferable in view of securing conduction reliability. Examples of the metal-coated resin particles include resin particles in each of which a resin is coated with Ni, and resin particles in each of which a resin core is coated with Ni, and the outer surface thereof is further coated with Au.

A method for coating the resin core with Ni or Au is appropriately selected depending on the intended purpose without any limitation, and examples thereof include electroless plating, and sputtering.

A material of the resin core is appropriately selected depending on the intended purpose without any limitation, and examples thereof include a styrene-divinyl benzene copolymer, a benzoguanamine resin, a crosslinked polystyrene resin, an acrylic resin, and a styrene-silica composite resin. Among them, the styrene-divinyl benzene copolymer is particularly preferable because it can allow the resulting particles to be soft and flexible to thereby increase contact areas upon compression and to secure excellent conduction reliability.

The hardness of the metal-coated resin particles is, for example, preferably 50 kgf/mm² to 500 kgf/mm². The hardness of the metal-coated resin particles can be determined, for example, from test force obtained by applying load to the metal-coated resin particles by means of a micro compression tester to make the metal-coated resin particles displace by 10%.

The difference (A-B) between the hardness (A) of the Ni particles and the hardness (B) of the metal-coated resin particles is preferably 1,500 kgf/mm² or greater, more preferably 2,000 kgf/mm² to 5,000 kgf/mm². When the difference (A-B) is less than 1,500 kgf/mm², the hardness of Ni particles themselves is insufficient, and thus the Ni particles cannot break the metal oxide film on the electrode pattern, which may cause a conduction failure.

The metal-coated resin particles may be appropriately prepared for use, or selected from commercial products.

The average particle diameter of the metal-coated resin particles is preferably 5 μm or greater, more preferably 9 μm to 11 μm. When the average particle diameter is smaller than 5 μm, repulsive force of the metal-coated resin particles may be low at the time of pressure bonding, which may cause a problem in the connection reliability.

The average particle diameter of the metal⁻coated resin particles represents the number average particle diameter thereof, and it can be measured, for example, by a particle size distribution analyzer (MICROTRAC MT3100, manufactured by Nikkiso Co., Ltd.).

An amount of the metal-coated resin particles in the electric conductive layer is appropriately selected depending on the intended purpose without any limitation, but it is preferably 2 parts by mass to 10 parts by mass, more preferably 2 parts by mass to 8 parts by mass, relative to 100 parts by mass of resin solids (a total amount of the binder, the polymerizable monomer, and the curing agent). When the amount thereof is excessively small, the conduction resistance may increase. When the amount thereof is excessively large, it is more likely to cause short circuit.

A total amount of the Ni particles and the metal-coated resin particles in the electric conductive layer is preferably 3 parts by mass to 20 parts by mass, more preferably 5 parts by mass to 10 parts by mass, relative to 100 parts by mass of the resin solids of the electric conductive layer. When the amount thereof is excessively small, the conduction resistance may increase. When the amount thereof is excessively large, it is more likely to cause short circuit.

### —Polymerizable Monomer—

The polymerizable monomer is not particularly limited, and a monofunctional and/or polyfunctional polymerizable monomer can be used as the polymerizable monomer. Examples thereof include a monofunctional (meth)acrylmonomer, bifunctional (meth)acrylmonomer, and trifunctional (meth)acrylmonomer. These may be used independently, or in combination.

An amount of the polymerizable monomer in the electric conductive layer is appropriately selected depending on the intended purpose without any limitation, but it is preferably 3% by mass to 60% by mass, more preferably 5% by mass to 50% by mass.

—Binder, Curing Agent, Silane Coupling Agent, and other Components—

As for a binder, a curing agent, a silane coupling agent, and other components in the electric conductive layer, materials that are same to the binder, the curing agent, the silane coupling agent, and other components in the insulating layer are respectively used in the same amounts in the insulating layer.

The electric conductive layer can be formed by preparing a coating liquid for an electric conductive layer containing, for example, Ni particles, metal⁻coated resin particles, a binder, a polymerizable monomer, and a curing agent, preferably further containing a silane coupling agent, and optionally further containing other components, and applying the coating liquid for an electric conductive layer onto the insulating layer.

A thickness of the electric conductive layer is appropriately selected depending on the intended purpose without any limitation. For example, the thickness thereof is preferably 10 μm to 25 μm, more preferably 15 μm to 20 μm. When the thickness thereof is excessively small, the conduction reliability may be impaired. When the thickness thereof is excessively large, the peel strength may be reduced.

A thickness of the anisotropic conductive film combining the insulating layer and the electric conductive layer is preferably 25 μm to 55 μm, more preferably 30 μm to 50 μm. When the thickness thereof is excessively small, a joined structure formed using the resulting anisotropic conductive film may have insufficient peel strength due to lack of filling. When the thickness thereof is excessively large, conduction failure may occur because of insufficient ability of the anisotropic conductive film on absorbing shapes of other members as pressed.

### —Separation Base—

A shape, structure, size, thickness, and material of the separation base are appropriately selected depending on the intended purpose without any limitation, but the separation base is preferably selected from those having excellent release properties, or those having high heat resistance. Examples of the separation base include a transparent release PET(polyethylene terephthalate) sheet or PTFE (polytetrafluoroethylene) sheet onto which a releasing agent (e.g. silicone) has been applied.

A thickness of the separation base is appropriately selected depending on the intended purpose without any limitation, and for example, it is preferably 10 μm to 100 μm, more preferably 20 μm to 80 μm.

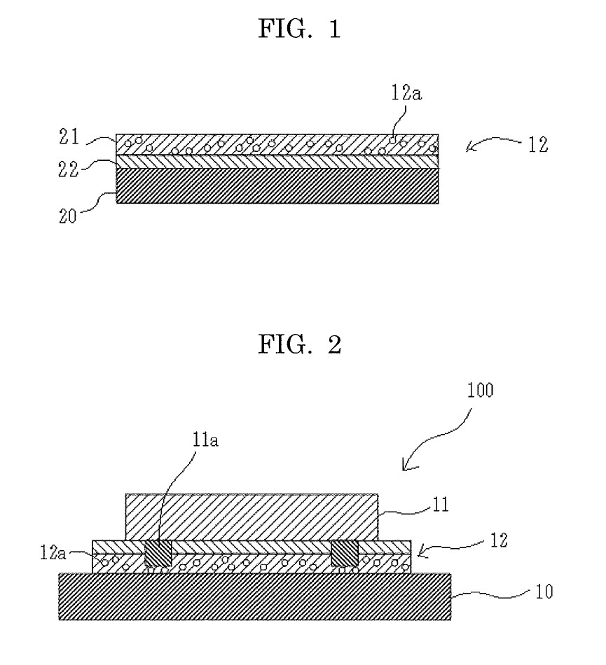

The anisotropic conductive film of the present invention contains, as illustrated in FIG. 1, a separation base (separator) 20, an insulating layer 22 formed on the separation base (separator) 20, and an electric conductive layer 21 formed on the insulating layer 22. In the electric conductive layer 21, electric conductive particles 12a (Ni particles and Ni/Au-plated resin particles) are dispersed.

As illustrated in FIG. 2, this anisotropic conductive film 12 is joined in the manner that the electric conductive layer 21 thereof comes to the side of the PWB 10. Thereafter, the separation base (separator) 20 is released, and a COF 11 is pressure bonded to the anisotropic conductive film 12 from the side of the insulating layer 22, to thereby form a joined structure 100. In FIG. 2, the numeral reference 11a represents a terminal.

### (Joined Structure)

The joined structure of the present invention contains a first circuit member, a second circuit member, and the anisotropic conductive film of the present invention, and may further contain other members, if necessary.

The first circuit member and the second circuit member are joined together with the anisotropic conductive film, which is present between the first circuit member and the second circuit member.

### First Circuit Member—

The first circuit member is appropriately selected depending on the intended purpose without any limitation, and examples thereof include a FPC, and a PWB. Among them, the PWB is particularly preferable.

### —Second Circuit Member—

The second circuit member is appropriately selected depending on the intended purpose without any limitation, and examples thereof include a FPC, COF (Chip On Film), a TCP, a PWB, an IC board, and a panel. Among them, the COF is particularly preferable.

In the joined structure, the anisotropic conductive film is joined to the first circuit member so that the electric conductive layer of the anisotropic conductive film comes to the side of a printed wiring board serving as the first circuit member, and the separation base is released from the anisotropic conductive film to thereby join the insulating layer of the anisotropic conductive film to the second circuit member in the manner that the insulating layer comes to the side of a COF serving as the second circuit member.

### (Connecting Method)

The connecting method of the present invention contains: providing an anisotropic conductive film between a first circuit member and a second circuit member; and pressurizing the first circuit member and the second circuit member with heating to cure the anisotropic conductive film, to thereby connect the first circuit member with the second circuit member.

In this case, it is preferred that the first circuit member be a printed wiring board, and the second circuit member be a COF.

It is preferred that the anisotropic conductive film be provided so that the electric conductive layer of the anisotropic conductive film comes to the side of the printed wiring board, and the insulating layer thereof comes to the side of the COF. The printed wiring board and the COF are joined together by pressurizing from the top surface of the COF with heating.

### —Conditions of Pressure Bonding—

The heating is determined by a total heat capacity. In the case where the bonding is completed with the contact time of 10 seconds or shorter, the heating is preferably performed at the temperature of 120° C. to 220° C.

The conditions of the pressure bonding cannot be determined unconditionally, as they vary depending on a type of the second circuit member for use. For example, in the case where the second circuit member is a TAB tape, the pressure bonding is preferably performed at the pressure of 2 MPa to 6 MPa for 3 seconds to 10 seconds. In the case where the second circuit member is an IC chip, the pressure bonding is preferably performed at the pressure of 20 MPa to 120 MPa for 3 seconds to 10 seconds. In the case where the second circuit member is a COF, the pressure bonding is preferably performed at the pressure of 2 MPa to 6 MPa for 3 seconds to 10 seconds.

### EXAMPLE

Examples of the present invention will be explained hereinafter, but these examples shall not be construed as limiting the scope of the present invention in any way.

### <Measurement of Average Particle Diameter of Ni Particles or Resin Particles>

The average particle diameter of the Ni particles or resin particles was measured by means of a particle size distribution analyzer (MICROTRAC MT3100, manufactured by Nikkiso Co., Ltd.).

### Production Example 1

### —Production of Ni Particles—

Nickel Powder Type T255 of Vale Inco was classified to give the average particle diameter of 3 μm, to thereby obtain Ni particles.

### Production Example 2

### —Production of Au-Plated Ni Particles—

After classifying Nickel Powder Type T255 of Vale Inco to give the average particle diameter of 3 μm, the resulting Ni particles were subjected to displacement plating to plate Au on surfaces of the Ni particles, to thereby produce Au-plated Ni particles.

### Production Example 3

### —Production of Ni-Plated Resin Particles—

Resin particles of a styrene-divinyl benzene copolymer having the average particle diameter of 10 μm were subjected to electroless plating to plate Ni on surfaces of the resin particles, to thereby produce Ni-plated resin particles.

### Production Example 4

—Production of Ni/Au-Plated Resin Particles A—

Resin particles of a styrene-divinylbenzene copolymer having the average particle diameter of 10 μm were subjected to electroless plating to plate Ni on surfaces of the resin particles. The resulting particles were further subjected to displacement plating to plate Au on the Ni-plated surface, to thereby produce Ni/Au-Plated Resin Particles A.

### Production Example 5

### —Production of Ni/Au-Plated Resin Particles B—

Crosslinked polystyrene particles having the average particle diameter of 10 μm were subjected to electroless plating to plate Ni on surfaces of the resin particles. The resulting particles were further subjected to displacement plating to plate Au on the Ni-plated surface, to thereby produce Ni/Au-Plated Resin Particles B.

### Production Example 6

### —Production of Ni/Au-Plated Resin Particles C—

Benzoguanamine particles having the average particle diameter of 5 μm were subjected to electroless plating to plate Ni on surfaces of the resin particles.

The resulting particles were further subjected to displacement plating to plate Au on the Ni-plated surface, to thereby produce Ni/Au-Plated Resin Particles C.

### Example 1

### <Production of Anisotropic Conductive Film 1>

### —Production of Insulating Layer 1—

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, and 3 parts by mass of dilauroyl peroxide (manufactured by NOF CORPORATION).

Next, the resulting mixed solution was applied onto a 50 μm-thick polyethylene terephthalate (PET) film, followed by dried in an oven of 80° C. for 5 minutes. Then, the PET film was released from the resultant, to thereby produce Insulating Layer 1 having a thickness of 18 μm.

### —Production of Electric Conductive Layer 1—

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 20 parts by mass of a bifunctional acryl monomer (product name: A-200, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, 3 parts by mass of dilauroyl peroxide (manufactured by NOF CORPORATION) serving as organic peroxide, 2.8 parts by mass of Ni particles (average particle diameter: 3 μm) of Production Example 1, and 3.8 parts by mass of Ni/Au-Plated Resin Particles C (average particle diameter: 5 μm, resin core: benzoguanamine resin) of Production Example 6.

Next, the resulting mixed solution was applied onto a 50 μm-thick polyethylene terephthalate (PET) film, followed by dried in an oven of 80° C. for 5 minutes. Then, the PET film was released from the resultant, to thereby produce Electric Conductive Layer 1 having a thickness of 17 μm.

Next, Insulating Layer 1 and Electric Conductive Layer 1 were laminated by a roller to bond together, to thereby produce Anisotropic Conductive Film 1 having a total thickness of 35 μm, having a two-layer structure consisting of Insulating Layer 1 and Electric Conductive Layer 1.

### —Production of Joined Structure—

Bonding of COF (thickness of polyimide film: 38 μm, thickness of Cu: 8μm, pitch: 200 82 m (line:space=1:1), Sn-plated product) or TCP (thickness of polyimide film: 75 μm, thickness of Cu: 18 μm, epoxy-based adhesive layer: 12 μm, pitch: 200 μm (line:space=1:1), Sn-plated product) with PWB (glassepoxy substrate, thickness of Cu: 35 μm, pitch: 200 μm (line:space=1:1), Au flash plated product) was performed using and providing Anisotropic Conductive Film 1 between them, to thereby produce Joined structure 1.

Note that, the bonding of COF or TCP with PWB was performed under the following conditions of pressure bonding.

### <Conditions of Pressure Bonding>

ACF width: 2.0 mm
Tool width: 2.0 mm
Buffer material: silicone rubber having a thickness of 0.2 mm
0.2 mm-pitched COF/PWB: 130° C., 3 MPa, 3 sec
0.2 mm-pitched TCP/PWB: 140° C., 3 MPa, 3 sec

Next, Anisotropic Conductive Film 1 and Joined structure 1 were subjected to the measurements of peel strength, and conduction resistance in the following manners. The results are presented in Table 1.

### <Measuring Method of Peel Strength>

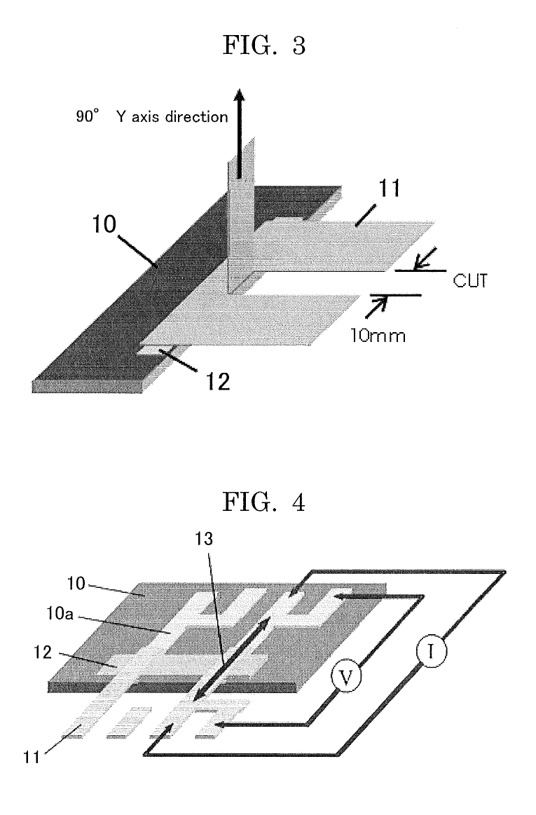

As illustrated in FIG. 3, peel strength of the produced joined structure was measured in the 90° Y axis direction at tensile strength of 50 mm/min. Since it was harder to adhere to the anisotropic conductive film to COF than adhering to TCP, peel strength was measured with the joined structure in which the anisotropic conductive film was adhered to COF. The result was evaluated in the following evaluation criteria. Note that, the result of the peel strength was depicted with the maximum value (N/cm). In FIG. 3, the numeral references 10, 11, and 12 respectively denote a PWB, a COF or TAB, and an ACF.

### [Evaluation Criteria]

I: Peel strength was 8 N/cm or higher.

II: Peel strength was lower than 8 N/cm.

### <Measuring Method of Conduction Resistance>

As illustrated in FIG. 4, conduction resistance of the produced joined structure [initial conduction resistance (Ω) and conduction resistance (Ω) after an environmental test (standing in the environment of 85° C., 85% RH for 1,000 hours)] was calculated from the voltage measured when the constant current of 1 mA was applied by means of a tester in accordance with a 4-terminal method. The results were evaluated based on the following evaluation criteria. Since conduction reliability with TCP was more severe than that with COF, conduction resistance was measured only with respect to TCP. Note that, in FIG. 4, the numeral references 10, 10a, 11, 12, and 13 respectively denote a PWB, wiring of the PWB, pattern of COF or TAB, an ACF, and an actual measuring point.

### [Evaluation Criteria of Initial Conduction Resistance]

I: Conduction resistance was 0.060Ω or lower.

II: Conduction resistance was higher than 0.060 Ω

[Evaluation Criteria of Conduction Resistance after Environmental Test (after Standing in the Environment of 85° C., 85% RH for 1,000 hours)]

A: The value of (initial conduction resistance/conduction resistance after the environmental test) was less than 5.

B: The value of (initial conduction resistance/conduction resistance after the environmental test) was 5 or more, but less than 11.

C: The value of (initial conduction resistance/conduction resistance after the environmental test) was 11 or more.

### Example 2

### <Production and Evaluation of Anisotropic Conductive Film 2>

Anisotropic Conductive Film 2 having a total thickness of 35 μm and having a two-layer structure consisting of Insulating Layer 1 and Electric Conductive Layer 2 as well as Joined structure 2 were produced in the same manner as in Example 1, provided that Electric Conductive Layer 1 was replaced with Electric Conductive Layer 2.

Produced Anisotropic Conductive Film 2 and Joined structure 2 were subjected to measurements of peel strength, and conduction resistance in the same manner as in Example 1. The results are presented in Table 1.

### —Production of Electric Conductive Layer 2—

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 20 parts by mass of a bifunctional acryl monomer (product name: A-200, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, 3 parts by mass of dilauroyl peroxide (manufactured by NOF CORPORATION) serving as organic peroxide, 2.8 parts by mass of Ni particles (average particle diameter: 3 μm) of Production Example 1, and 3.8 parts by mass of Ni/Au-Plated Resin Particles B (average particle diameter: 10 μm, resin core: crosslinked polystyrene) of Production Example 5.

Next, the resulting mixed solution was applied onto a 50 μm-thick polyethylene terephthalate (PET) film, followed by dried in an oven of 80° C. for 5 minutes. Then, the PET film was released from the resultant, to thereby produce Electric Conductive Layer 2 having a thickness of 17 μm.

### Example 3

### <Production of Anisotropic Conductive Film 3>

Anisotropic Conductive Film 3 having a total thickness of 35 μm and having a two-layer structure consisting of Insulating Layer 1 and Electric Conductive Layer 3 as well as Joined structure 3 were produced in the same manner as in Example 1, provided that Electric Conductive Layer 1 was replaced with Electric Conductive Layer 3.

Produced Anisotropic Conductive Film 3 and Joined structure 3 were subjected to measurements of peel strength, and conduction resistance in the same manner as in Example 1. The results are presented in Table 1.

### —Production of Electric Conductive Layer 3—

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 20 parts by mass of a bifunctional acryl monomer(product name: A-200, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, 3 parts by mass of dilauroyl peroxide(manufactured by NOF CORPORATION) serving as organic peroxide, 2.8 parts by mass of Ni particles (average particle diameter: 3 μm) of Production Example 1, and 3.8 parts by mass of Ni/Au-Plated Resin Particles A (average particle diameter: 10 μm, resin core: a styrene-divinylbenzene copolymer) of Production Example 4.

Next, the resulting mixed solution was applied onto a 50 μm-thick polyethylene terephthalate (PET) film, followed by dried in an oven of 80° C. for 5 minutes. Then, the PET film was released from the resultant, to thereby produce Electric Conductive Layer 3 having a thickness of 17 μm.

### Example 4

### <Production of Anisotropic Conductive Film 4>

Anisotropic Conductive Film 4 having a total thickness of 35 μm and having a two-layer structure consisting of Insulating Layer 1 and Electric Conductive Layer 4 as well as Joined structure 4 were produced in the same manner as in Example 1, provided that Electric Conductive Layer 1 was replaced with Electric Conductive Layer 4.

Produced Anisotropic Conductive Film 4 and Joined structure 4 were subjected to measurements of peel strength, and conduction resistance in the same manner as in Example 1. The results are presented in Table 1.

### —Production of Electric Conductive Layer 4—

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 20 parts by mass of a bifunctional acryl monomer (product name: A-200, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, 3 parts by mass of dilauroyl peroxide (manufactured by NOF CORPORATION) serving as organic peroxide, 2.8 parts by mass of Ni particles (average particle diameter: 3 μm) of Production Example 1, and 3.8 parts by mass of Ni-plated resin particles (average particle diameter: 10 μm, resin core: a styrene-divinylbenzene copolymer) of Production Example 3.

Next, the resulting mixed solution was applied onto a 50 μm-thick polyethylene terephthalate (PET) film, followed by dried in an oven of 80° C. for 5 minutes. Then, the PET film was released from the resultant, to thereby produce Electric Conductive Layer 4 having a thickness of 17 μm.

### Example 5

### <Production of Anisotropic Conductive Film 5>

Anisotropic Conductive Film 5 having a total thickness of 35 μm and having a two-layer structure consisting of Insulating Layer 1 and Electric Conductive Layer 5 as well as Joined structure 5 were produced in the same manner as in Example 1, provided that Electric Conductive Layer 1 was replaced with Electric Conductive Layer 5.

Produced Anisotropic Conductive Film 5 and Joined structure 5 were subjected to measurements of peel strength, and conduction resistance in the same manner as in Example 1. The results are presented in Table 1.

### —Production of Electric Conductive Layer 5—

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 20 parts by mass of a bifunctional acryl monomer (product name: A-200, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, 3 parts by mass of dilauroyl peroxide (manufactured by NOF CORPORATION) serving as organic peroxide, 1.9 parts by mass of Ni particles (average particle diameter: 3 μm) of Production Example 1, and 1.1 parts by mass of Ni/Au-Plated Resin Particles A (average particle diameter: 10 μm, resin core: a styrene-divinylbenzene copolymer) of Production Example 4.

Next, the resulting mixed solution was applied onto a 50 μm-thick polyethylene terephthalate (PET) film, followed by dried in an oven of 80° C. for 5 minutes. Then, the PET film was released from the resultant, to thereby produce Electric Conductive Layer 5 having a thickness of 17 μm.

### Comparative Example 1

### <Production of Anisotropic Conductive Film 6>

Anisotropic Conductive Film 6 having a total thickness of 35 μm and having a two-layer structure consisting of Insulating Layer 1 and Electric Conductive Layer 6 as well as Joined structure 6 were produced in the same manner as in Example 1, provided that Electric Conductive Layer 1 was replaced with Electric Conductive Layer 6.

Produced Anisotropic Conductive Film 6 and Joined structure 6 were subjected to measurements of peel strength, and conduction resistance in the same manner as in Example 1. The results are presented in Table 1.

### —Production of Electric Conductive Layer 6—

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 20 parts by mass of a bifunctional acryl monomer (product name: A-200, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, 3 parts by mass of dilauroyl peroxide (manufactured by NOF CORPORATION) serving as organic peroxide, and 2.8 parts by mass of Ni particles (average particle diameter: 3 μm) of Production Example 1.

Next, the resulting mixed solution was applied onto a 50 μm-thick polyethylene terephthalate (PET) film, followed by dried in an oven of 80° C. for 5 minutes. Then, the PET film was released from the resultant, to thereby produce Electric Conductive Layer 6 having a thickness of 17 μm.

### Comparative Example 2

### <Production of Anisotropic Conductive Film 7>

Anisotropic Conductive Film 7 having a total thickness of 35 μm and having a two-layer structure consisting of Insulating Layer 1 and Electric Conductive Layer 7 as well as Joined structure 7 were produced in the same manner as in Example 1, provided that Electric Conductive Layer 1 was replaced with Electric Conductive Layer 7.

Produced Anisotropic Conductive Film 7 and Joined structure 7 were subjected to measurements of peel strength, and conduction resistance in the same manner as in Example 1. The results are presented in Table 1.

### —Production of Electric Conductive Layer 7—

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 20 parts by mass of a bifunctional acryl monomer (product name: A-200, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, 3 parts by mass of dilauroyl peroxide (manufactured by NOF CORPORATION) serving as organic peroxide, and 3.8 parts by mass of Ni/Au-Plated Resin Particles A (average particle diameter: 10 μm, resin core: a styrene-divinylbenzene copolymer) of Production Example 4.

Next, the resulting mixed solution was applied onto a 50 μm-thick polyethylene terephthalate (PET) film, followed by dried in an oven of 80° C. for 5 minutes. Then, the PET film was released from the resultant, to thereby produce Electric Conductive Layer 7 having a thickness of 17 μm.

### Comparative Example 3

### <Production of Anisotropic Conductive Film 8>

Anisotropic Conductive Film 8 having a total thickness of 35 μm and having a two-layer structure consisting of Insulating Layer 2 and Electric Conductive Layer 3 as well as Joined structure 8 were produced in the same manner as in Example 3, provided that Insulating Layer 1 was replaced with Insulating Layer 2.

Produced Anisotropic Conductive Film 8 and Joined structure 8 were subjected to measurements of peel strength, and conduction resistance in the same manner as in Example 1. The results are presented in Table 1.

### —Production of Insulating Layer 2—

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 20 parts by mass of a bifunctional acryl monomer (product name: A-200, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, and 3 parts by mass of dilauroyl peroxide (manufactured by NOF CORPORATION) serving as organic peroxide. Next, the resulting mixed solution was applied onto a 50 μm-thick polyethylene terephthalate (PET) film, followed by dried in an oven of 80° C. for 5 minutes. Then, the PET film was released from the resultant, to thereby produce Insulating Layer 2 having a thickness of 18 μm.

### Comparative Example 4

### <Production of Anisotropic Conductive Film 9>

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U⁻2PPA, manufactured by Shin-Nakamura Chemical Co., Ltd.), 20 parts by mass of a bifunctional acryl monomer (product name: A-200, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, 3 parts by mass of dilauroyl peroxide (manufactured by NOF CORPORATION) serving as organic peroxide, 2.8 parts by mass of Ni particles (average particle diameter: 3 μm) of Production Example 1, and 3.8 parts by mass of Ni/Au-Plated Resin Particles A (average particle diameter: 10 μm, resin core: a styrene-divinylbenzene copolymer) of Production Example 4.

Next, the resulting mixed solution was applied onto a 50 μm-thick polyethylene terephthalate (PET) film, followed by dried in an oven of 80° C. for 5 minutes. Then, the PET film was released from the resultant, to thereby produce Anisotropic Conductive Film 9 consisting of Electric Conductive Layer 3 having a thickness of 35 μm.

Using Anisotropic Conductive Film 9, Joined structure 9 was produced in the same manner as in Example 1, and was subjected to the measurements of peel strength, and conduction resistance in the same manner as in Example 1. The results are presented in Table 1.

### Comparative Example 5

### <Production of Anisotropic Conductive Film 10>

A mixed solution of ethyl acetate and toluene was prepared to have the solid content of 50% by mass, in which the mixed solution contained 45 parts by mass of a phenoxy resin (product name: YP-50, manufactured by Nippon Steel Chemical Co., Ltd.), 20 parts by mass of urethane acrylate (product name: U-2PPA, manufactured by Shin-Nakamura Chemical Co., Ltd.), 10 parts by mass of a monofunctional acryl monomer (product name: 4-HBA, manufactured by Osaka Organic Chemical Industry Ltd.), 2 parts by mass of phosphoric acid ester-type acrylate (product name: PM-2, manufactured by Nippon Kayaku Co., Ltd.), 3 parts by mass of benzoyl peroxide (manufactured by NOF CORPORATION) serving as organic peroxide, 3 parts by mass of dilauroyl peroxide (manufactured by NOF CORPORATION) serving as organic peroxide, 2.8 parts by mass of Au-plated Ni particles (average particle diameter: 3 μm) of Production Example 2, and 3.8 parts by mass of Ni/Au-Plated Resin Particles B (average particle diameter: 10 μm, resin core: crosslinked polystyrene) of Production Example 5.

Next, the resulting mixed solution was applied onto a 50 μm-thick polyethylene terephthalate (PET) film, followed by dried in an oven of 80° C. for 5 minutes. Then, the PET film was released from the resultant, to thereby produce Anisotropic Conductive Film 10 consisting of Electric Conductive Layer 8 having a thickness of 35 μm.

Using Anisotropic Conductive Film 10, Joined structure 10 was produced in the same manner as in Example 1, and was subjected to the measurements of peel strength, and conduction resistance in the same manner as in Example 1. The results are presented in Table 1.

TABLE 1

| | | Ex. 1 | | Ex. 2 | |
|---|---|---|---|---|---|
| | | Anisotropic conductive film | | | |
| | | 1 | | 2 | |
| | | | Electric | | Electric |
| | | Insulating | Conductive | Insulating | Conductive |
| | | Layer 1 | Layer 1 | Layer 1 | Layer 2 |
| Portion in contact with anisotropic conductive film | | Film side | PWB side | Film side | PWB side |
| 1 | YP-50 (Bis A epoxy-type phenoxy resin) | 45 | 45 | 45 | 45 |
| 2 | U-2PPA (urethane acrylate) | 20 | 20 | 20 | 20 |
| 3 | A-200 (bifunctional acryl monomer) | — | 20 | — | 20 |
| 4 | 4-HBA (monofunctional acryl monomer) | 10 | 10 | 10 | 10 |
| 5 | PM-2 (phosphoric acid ester-type acrylate) | 2 | 2 | 2 | 2 |
| 6 | Dibenzoyl peroxide (organic peroxide) | 3 | 3 | 3 | 3 |
| 7 | Dilauroyl peroxide (organic peroxide) | 3 | 3 | 3 | 3 |
| 8 | Ni particles | — | 2.8 | — | 2.8 |
| | (average particle diameter: 3 μm) | | | | |
| 9 | Au-plated Ni particles | — | — | — | — |
| | (average particle diameter: 3 μm) | | | | |
| 10 | Ni-plated resin particles | — | — | — | — |
| | (average particle diameter: 10 μm) | | | | |
| | Resin core: styrene-divinylbenzene copolymer | | | | |
| 11 | Ni/Au-Plated Resin Particles A | — | — | — | — |
| | (average particle diameter: 10 μm) | | | | |
| | Resin core: styrene-divinylbenzene copolymer | | | | |
| 12 | Ni/Au-Plated Resin Particles B | — | — | — | 3.8 |
| | (average particle diameter: 10 μm) | | | | |
| | Resin core: crosslinked polystyrene | | | | |
| 13 | Ni/Au-Plated Resin Particles C | — | 3.8 | — | — |
| | (average particle diameter: 5 μm) | | | | |
| | Resin core: benzoguanamine resin | | | | |

| Evaluation items | | Result | Evaluation | Result | Evaluation |
|---|---|---|---|---|---|
| Peal strength (N/cm) | COF/PWB | 10.0 | I | 11.1 | I |
| Max value of initial conduction | TCP/PWB | 0.047 | I | 0.046 | I |
| resistance (Ω) | | | | | |
| Conduction resistance (Ω) after | TCP/PWB | 0.278 | B | 0.450 | B |
| storing in 85° C. 85% for 1,000 hr | | | | | |

| | | Ex. 3 | | Ex. 4 | |
|---|---|---|---|---|---|
| | | Anisotropic conductive film | | | |
| | | 3 | | 4 | |
| | | | Electric | | Electric |
| | | Insulating | Conductive | Insulating | Conductive |
| | | Layer 1 | Layer 3 | Layer 1 | Layer 4 |
| Portion in contact with anisotropic conductive film | | Film side | PWB side | Film side | PWB side |
| 1 | YP-50 (Bis A epoxy-type phenoxy resin) | 45 | 45 | 45 | 45 |
| 2 | U-2PPA (urethane acrylate) | 20 | 20 | 20 | 20 |
| 3 | A-200 (bifunctional acryl monomer) | — | 20 | — | 20 |
| 4 | 4-HBA (monofunctional acryl monomer) | 10 | 10 | 10 | 10 |
| 5 | PM-2 (phosphoric acid ester-type acrylate) | 2 | 2 | 2 | 2 |
| 6 | Dibenzoyl peroxide (organic peroxide) | 3 | 3 | 3 | 3 |
| 7 | Dilauroyl peroxide (organic peroxide) | 3 | 3 | 3 | 3 |
| 8 | Ni particles | — | 2.8 | — | 2.8 |
| | (average particle diameter: 3 μm) | | | | |
| 9 | Au-plated Ni particles | — | — | — | — |
| | (average particle diameter: 3 μm) | | | | |
| 10 | Ni-plated resin particles | — | — | — | 3.8 |
| | (average particle diameter: 10 μm) | | | | |
| | Resin core: styrene-divinylbenzene copolymer | | | | |
| 11 | Ni/Au-Plated Resin Particles A | — | 3.8 | — | — |
| | (average particle diameter: 10 μm) | | | | |
| | Resin core: styrene-divinylbenzene copolymer | | | | |
| 12 | Ni/Au-Plated Resin Particles B | — | — | — | — |
| | (average particle diameter: 10 μm) | | | | |
| | Resin core: crosslinked polystyrene | | | | |
| 13 | Ni/Au-Plated Resin Particles C | — | — | — | — |
| | (average particle diameter: 5 μm) | | | | |
| | Resin core: benzoguanamine resin | | | | |

| Evaluation items | | Result | Evaluation | Result | Evaluation |
|---|---|---|---|---|---|
| Peal strength (N/cm) | COF/PWB | 10.4 | I | 10.2 | I |
| Max value of initial conduction | TCP/PWB | 0.049 | I | 0.045 | I |
| resistance (Ω) | | | | | |
| Conduction resistance (Ω) after storing | TCP/PWB | 0.099 | A | 0.105 | A |
| in 85° C. 85% for 1,000 hr | | | | | |

| | | Ex. 5 | |
|---|---|---|---|
| | | Anisotropic conductive film | |
| | | 5 | |
| | | | Electric |
| | | Insulating | Conductive |
| | | Layer 1 | Layer 5 |
| Portion in contact with anisotropic conductive film | | Film side | PWB side |
| 1 | YP-50 (Bis A epoxy-type phenoxy resin) | 45 | 45 |
| 2 | U-2PPA (urethane acrylate) | 20 | 20 |
| 3 | A-200 (bifunctional acryl monomer) | — | 20 |
| 4 | 4-HBA (monofunctional acryl monomer) | 10 | 10 |
| 5 | PM-2 (phosphoric acid ester-type acrylate) | 2 | 2 |
| 6 | Dibenzoyl peroxide (organic peroxide) | 3 | 3 |
| 7 | Dilauroyl peroxide (organic peroxide) | 3 | 3 |
| 8 | Ni particles (average particle diameter: 3 μm) | — | 1.9 |
| 9 | Au-plated Ni particles | — | — |
| | (average particle diameter: 3 μm) | | |
| 10 | Ni-plated resin particles (average particle diameter: | — | — |
| | 10 μm) | | |
| | Resin core: styrene-divinylbenzene copolymer | | |
| 11 | Ni/Au-Plated Resin Particles A (average particle | — | 1.1 |
| | diameter: 10 μm) | | |
| | Resin core: styrene-divinylbenzene copolymer | | |
| 12 | Ni/Au-Plated Resin Particles B (average particle | — | — |
| | diameter: 10 μm) | | |
| | Resin core: crosslinked polystyrene | | |
| 13 | Ni/Au-Plated Resin Particles C (average particle | — | — |
| | diameter: 5 μm) | | |
| | Resin core: benzoguanamine resin | | |

| Evaluation items | | Result | Evaluation |
|---|---|---|---|
| Peal strength (N/cm) | COF/PWB | 10.6 | I |
| Max value of initial conduction | TCP/PWB | 0.054 | I |
| resistance (Ω) | | | |
| Conduction resistance (Ω) after | TCP/PWB | 0.588 | B |
| storing in 85° C. 85% for 1,000 hr | | | |

| | | Comp. Ex. 1 | | Comp. Ex. 2 | |
|---|---|---|---|---|---|
| | | Anisotropic conductive film | | | |
| | | 6 | | 7 | |
| | | | Electric | | Electric |
| | | Insulating | Conductive | Insulating | Conductive |
| | | Layer 1 | Layer 6 | Layer 1 | Layer 7 |
| Portion in contact with anisotropic conductive film | | Film side | PWB side | Film side | PWB side |
| 1 | YP-50 (Bis A epoxy-type phenoxy resin) | 45 | 45 | 45 | 45 |
| 2 | U-2PPA (urethane acrylate) | 20 | 20 | 20 | 20 |
| 3 | A-200 (bifunctional acryl monomer) | — | 20 | — | 20 |
| 4 | 4-HBA (monofunctional acryl monomer) | 10 | 10 | 10 | 10 |
| 5 | PM-2 (phosphoric acid ester-type acrylate) | 2 | 2 | 2 | 2 |
| 6 | Dibenzoyl peroxide (organic peroxide) | 3 | 3 | 3 | 3 |
| 7 | Dilauroyl peroxide (organic peroxide) | 3 | 3 | 3 | 3 |
| 8 | Ni particles | | 2.8 | | |
| | (average particle diameter: 3 μm) | | | | |
| 9 | Au-plated Ni particles | — | — | — | — |
| | (average particle diameter: 3 μm) | | | | |
| 10 | Ni-plated resin particles | — | — | — | — |
| | (average particle diameter: 10 μm) | | | | |
| | Resin core: styrene-divinylbenzene copolymer | | | | |
| 11 | Ni/Au-Plated Resin Particles A | — | — | — | 3.8 |
| | (average particle diameter: 10 μm) | | | | |
| | Resin core: styrene-divinylbenzene copolymer | | | | |
| 12 | Ni/Au-Plated Resin Particles B | — | — | — | — |
| | (average particle diameter: 10 μm) | | | | |
| | Resin core: crosslinked polystyrene | | | | |
| 13 | Ni/Au-Plated Resin Particles C | — | — | — | — |
| | (average particle diameter: 5 μm) | | | | |
| | Resin core: benzoguanamine resin | | | | |

| Evaluation items | | Result | Evaluation | Result | Evaluation |
|---|---|---|---|---|---|
| Peal strength (N/cm) | COF/PWB | 10.5 | I | 11.3 | I |
| Max value of initial conduction | TCP/PWB | 0.044 | I | 0.068 | II |
| resistance (Ω) | | | | | |
| Conduction resistance (Ω) after storing | TCP/PWB | 0.595 | C | 27.874 | C |
| in 85° C. 85% for 1,000 hr | | | | | |

| | | Comp. Ex. 3 | | Comp. Ex. 4 |
|---|---|---|---|---|
| | | Anisotropic conductive film | | |
| | | 8 | | |
| | | | Electric | 9 |
| | | Insulating | Conductive | Electric Conductive |
| | | Layer 2 | Layer 3 | Layer 3 |
| Portion in contact with anisotropic conductive film | | Film side | PWB side | Film and PWB |
| 1 | YP-50 (Bis A epoxy-type phenoxy resin) | 45 | 45 | 45 |
| 2 | U-2PPA (urethane acrylate) | 20 | 20 | 20 |
| 3 | A-200 (bifunctional acryl monomer) | 20 | 20 | 20 |
| 4 | 4-HBA (monofunctional acryl monomer) | 10 | 10 | 10 |
| 5 | PM-2 (phosphoric acid ester-type acrylate) | 2 | 2 | 2 |
| 6 | Dibenzoyl peroxide (organic peroxide) | 3 | 3 | 3 |
| 7 | Dilauroyl peroxide (organic peroxide) | 3 | 3 | 3 |
| 8 | Ni particles | — | 2.8 | 2.8 |
| | (average particle diameter: 3 μm) | | | |
| 9 | Au-plated Ni particles | — | — | — |
| | (average particle diameter: 3 μm) | | | |
| 10 | Ni-plated resin particles | — | — | — |
| | (average particle diameter: 10 μm) | | | |
| | Resin core: styrene-divinylbenzene copolymer | | | |
| 11 | Ni/Au-Plated Resin Particles A | — | 3.8 | 3.8 |
| | (average particle diameter: 10 μm) | | | |
| | Resin core: styrene-divinylbenzene copolymer | | | |
| 12 | Ni/Au-Plated Resin Particles B | — | — | — |
| | (average particle diameter: 10 μm) | | | |
| | Resin core: crosslinked polystyrene | | | |
| 13 | Ni/Au-Plated Resin Particles C | — | — | — |
| | (average particle diameter: 5 μm) | | | |
| | Resin core: benzoguanamine resin | | | |

| Evaluation items | | Result | Evaluation | Result | Evaluation |
|---|---|---|---|---|---|
| Peal strength (N/cm) | COF/PWB | 5.5 | II | 5.7 | II |
| Max value of initial conduction | TCP/PWB | 0.045 | I | 0.043 | I |
| resistance (Ω) | | | | | |
| Conduction resistance (Ω) after storing | TCP/PWB | 0.091 | A | 0.088 | A |
| in 85° C. 85% for 1,000 hr | | | | | |

| | | Comp. Ex. 5 |
|---|---|---|
| | | Anisotropic conductive film |
| | | 10 |
| | | Electric Conductive |
| | | Layer 8 |
| Portion in contact with anisotropic conductive film | | Film and PWB |
| 1 | YP-50 (Bis A epoxy-type phenoxy resin) | 45 |
| 2 | U-2PPA (urethane acrylate) | 20 |
| 3 | A-200 (bifunctional acryl monomer) | — |
| 4 | 4-HBA (monofunctional acryl monomer) | 10 |
| 5 | PM-2 (phosphoric acid ester-type acrylate) | 2 |
| 6 | Dibenzoyl peroxide (organic peroxide) | 3 |
| 7 | Dilauroyl peroxide (organic peroxide) | 3 |
| 8 | Ni particles (average particle diameter: 3 μm) | — |
| 9 | Au-plated Ni particles (average particle diameter: | 2.8 |
| | 3 μm) | |
| 10 | Ni-plated resin particles (average particle | — |
| | diameter: 10 μm) | |
| | Resin core: styrene-divinylbenzene copolymer | |
| 11 | Ni/Au-Plated Resin Particles A (average particle | — |
| | diameter: 10 μm) | |
| | Resin core: styrene-divinylbenzene copolymer | |
| 12 | Ni/Au-Plated Resin Particles B (average particle | 3.8 |
| | diameter: 10 μm) | |
| | Resin core: crosslinked polystyrene | |
| 13 | Ni/Au-Plated Resin Particles C (average particle | — |
| | diameter: 5 μm) | |
| | Resin core: benzoguanamine resin | |

| Evaluation items | | Result | Evaluation |
|---|---|---|---|
| Peal strength (N/cm) | COF/PWB | 14.2 | I |
| Max value of initial conduction | TCP/PWB | 0.060 | I |
| resistance (Ω) | | | |
| Conduction resistance (Ω) after | TCP/PWB | Open | C |
| storing in 85° C. 85% for 1,000 hr | | (>100 Ω) | |

It was found from the results of Table 1 that Examples 1 to 5 and Comparative Examples 1, 2, and 5 exhibits high peel strength and excellent adhesion regardless of low temperature and short period pressure bonding conditions as 130° C., 3 MPa, and 3 sec.

Moreover, Examples 1 to 5 and Comparative Example 1, 4, and 5 had low conduction resistance, 0.06Ω or lower, which was excellent.

Any of Examples 3 and 4, and Comparative Examples 3 and 4 had low conduction resistance after being stood in the high temperature high humidity environment (85° C., 85% RH) for 1,000 hours, which was excellent.

Example 1 used the benzoguanamine resin having the average particle diameter of 5 μm as the resin cores of the metal-coated resin particles contained in the electric conductive layer, and had excellent peel strength and initial conduction resistance, but the repulsive force of the resin core itself was larger than that of the styrene-divinylbenzene copolymer, and the binder cured product was loosen in the environment of 85° C., 85% RH due to the repulsive force of the resin core. Therefore, Example 1 had slightly high conduction resistance after being stood in the high temperature and high humidity environment (85° C., 85% RH) for 1,000 hours.

Example 2 used the crosslinked polystyrene as the resin cores of the metal-coated resin particles contained in the electric conductive layer, and had excellent peel strength and initial conduction resistance, but the repulsive force of the resin core itself was larger than that of the styrene-divinylbenzene copolymer. Therefore, the binder cured product that pressed the particles was loosened in the high temperature and high humidity environment (85° C., 85% RH) by receiving the influence from the repulsive force thereof. Accordingly, Example 2 had slightly high conduction resistance after 1,000.

In Example 3, the insulating layer contained a monofunctional acryl monomer, and the electric conductive layer contained Ni particles and Ni/Au-Plated Resin Particles A (resin core: styrene-divinylbenzene copolymer, average particle diameter 10 μm), which was the best mode of the present invention.

In Example 4, a soft styrene-divinylbenzene copolymer was used as a resin core of the metal-coated resin particles contained in the electric conductive layer, and therefore the repulsive force of the resin core was weak, which easily crushed the particles, and increased contact areas between the particles and the electrode. Therefore, the low conduction resistance was obtained with the resin particles plated only with Ni after being stood in the high temperature high humidity environment (85° C., 85% RH) for 1,000 hours, which was the similar level to the conduction resistance obtained by using the Au/Ni plated resin particles.

In Example 5, a total amount of the Ni particles and Ni/Au-Plated Resin Particles A was 2.9 parts by mass relative to 100 parts by mass of the resin solids, which was a half or less of the total amount of Ni particles and Ni/Au-Plated Resin Particles A in the Example 3, 6.4 parts by mass, relative to 100 parts by mass of the resin solids in Example 3. Therefore, Example 5 had high conduction resistance after being stood in the high temperature and high humidity environment (85° C., 85% RH) for 1,000 hours.

Compared to the above, since the anisotropic conductive film of Comparative Example 1 contained only Ni particles in the electric conductive layer, the peel strength and initial conduction resistance were excellent, but the conduction resistance after being stood in the high temperature and high humidity environment (85° C., 85% RH) for 1,000 hours was high.

Since the electric conductive layer did not contain Ni particles but contains Ni/Au-Plated Resin Particles A in Comparative Example 2, the initial conduction resistance thereof was slightly higher than that in Example 3 (best mode), and the conduction resistance significantly increased after being stood in the high temperature and high humidity environment (85° C., 85% RH) for 1,000 hours. It is assumed that the conduction resistance significantly increased after being stood in the high temperature and high humidity environment (85° C., 85% RH) for 1,000 hours, as Ni/Au-Plated Resin Particles A alone could not break the oxide film formed on a surface of the PWB pattern to attain electric conductivity.

Since the insulating layer contains a bifunctional acryl monomer in Comparative Example 3, the peel strength was low, though the initial conduction resistance and the conduction resistance after being stood in the high temperature and high humidity environment (85° C., 85% RH) for 1,000 hours were excellent.

In Comparative Example 4, the anisotropic conductive film thereof consisted of a single layer of an electric conductive layer, and therefore the peel strength of the joined structure was low.

Comparative Example 5 was reproduction of Example disclosed in JP-A No. 11-339558, and the anisotropic conductive film thereof consisted of a single layer of an electric conductive layer. Since a curing reaction component was only a monofunctional monomer, the glass transition temperature (Tg) of the binder cured product was low (>85° C.), the binder cured product could not resist the repulsive force of the hard resin core particles in the high temperature and high humidity environment (85° C., 85% RH), and therefore the conduction resistance after 1,000 hours became open. In addition, the outer shells of the Ni particles were plated with soft Au, and therefore it was difficult for the particles to penetrate into the terminal and to break the oxide film. However, Comparative Example 5 had high peel strength, as only a monofunctional monomer was contained as the reaction component to thereby reduce the glass transition temperature (Tg).

The anisotropic conductive film of the present invention has high bonding strength with low temperature and short period pressure bonding conditions and has excellent conduction reliability, and therefore the anisotropic conductive film of the present invention can be suitably used for the connection between circuit members, such as a connection between a COF and a PWB, a connection between a TCP and a PWB, a connection between a COF and a glass substrate, a connection between a COF and a COF, a connection between an IC board and a glass substrate, and a connection between an IC board and a PWB.

What is claimed is:

1. An anisotropic conductive film, comprising:
an electric conductive layer containing Ni particles, metal-coated resin particles, a binder, a polymerizable monomer, and a curing agent; and
an insulating layer containing a binder, a monofunctional polymerizable monomer, and a curing agent,
wherein the metal-coated resin particles are resin particles each containing a resin core coated at least with Ni.

2. The anisotropic conductive film according to claim 1, wherein the insulating layer contains at least a phenoxy resin, a monofunctional (meth)acryl monomer, and organic peroxide.

3. The anisotropic conductive film according to claim 1, wherein the electric conductive layer contains at least a phenoxy resin, a (meth)acryl monomer, and organic peroxide.

4. The anisotropic conductive film according to claim 1, wherein the metal-coated resin particles are resin particles each containing a resin core coated with Ni, or resin particles each containing a resin core coated with Ni, whose outer surface is further coated with Au.

5. The anisotropic conductive film according to claim 1, wherein a material of the resin core is a styrene-divinylbenzene copolymer, or a benzoguanamine resin.

6. The anisotropic conductive film according to claim 1, wherein the metal-coated resin particles have the average particle diameter of 5 μm or greater.

7. The anisotropic conductive film according to claim 1, wherein a total amount of the Ni particles and the metal-coated resin particles in the electric conductive layer is 3.0 parts by mass to 20 parts by mass relative to 100 parts of resin solids contained in the electric conductive layer.

8. A joined structure, comprising:
a first circuit member;
a second circuit member; and
an anisotropic conductive film,
wherein the first circuit member and the second circuit member are joined together with the anisotropic conductive film provided between the first circuit member and the second circuit member, and
wherein the anisotropic conductive film contains:
an electric conductive layer containing Ni particles, metal-coated resin particles, a binder, a polymerizable monomer, and a curing agent; and
an insulating layer containing a binder, a monofunctional polymerizable monomer, and a curing agent,
wherein the metal-coated resin particles are resin particles each containing a resin core coated at least with Ni.

9. The joined structure according to claim 8, wherein the first circuit member is a printed wiring board and the second circuit member is a COF.

10. A connecting method, comprising:
providing an anisotropic conductive film between a first circuit member and a second circuit member; and
pressurizing the first circuit member and the second circuit member with heating to cure the anisotropic conductive film, to thereby connect the first circuit member with the second circuit member, wherein the anisotropic conductive film contains:
an electric conductive layer containing Ni particles, metal-coated resin particles, a binder, a polymerizable monomer, and a curing agent; and
an insulating layer containing a binder, a monofunctional polymerizable monomer, and a curing agent,
wherein the metal-coated resin particles are resin particles each containing a resin core coated at least with Ni.

11. The connecting method according to claim 10, wherein the first circuit member is a printed wiring board and the second circuit member is a COF.

12. The connecting method according to claim 11, wherein the providing is arranging the anisotropic conductive film so that the electric conductive layer thereof comes to the side of the printed wiring board, and the insulating layer thereof comes to the side of the COF.
